(19) United States
(12) Patent Application Publication
(10) Pub. No.: US 2005/0205417 A1
(43) Pub. Date: Sep. 22, 2005

(54) Method for cleaning the surface of an electrostatic chuck

(75) Inventors: Chi-Yun Chang, Hsinchu (TW); Yao-Pin Tsai, YangMei Town (TW)

Correspondence Address: BRUCE H. TROXELL;SUITE 1404, 5205 LEESBURG PIKE, FALLS CHURCH, VA, 22041, US

(73) Assignee: PSC Powerchip Semiconductor Corp.

(21) Appl. No.: 10/878,996

(22) Filed: Jun. 30, 2004

(30) Foreign Application Priority Data
Mar. 16, 2004 (TW) 93106909

(51) Int. Cl. C23C 14/32

(52) U.S. Cl. 204/192.32; 204/157.15

(57) ABSTRACT

A method for cleaning the surface of an electrostatic chuck of a semiconductor apparatus is disclosed. The semiconductor apparatus includes a sputtering chamber having an electrostatic chuck for holding a wafer. This method includes the steps of: adjusting the semiconductor apparatus to a cleaning state and a type of plasma is being generated at this time by which oxidative contaminant is removed, and adjusting the semiconductor apparatus to a discharging state to stop the plasma. The cleaning state includes at least three steps: inserting a protective gas, adjusting the RF power to an appropriate range, and maintaining the radio frequency power within the appropriate range for a period of time. The discharging state includes at least two steps: resetting the RF power of said electrostatic chuck to zero, and discharging the protective gas from the sputtering chamber.

### 1. FIELD OF THE INVENTION

The present invention relates to a method for cleaning a semiconductor apparatus and more particularly to a method for cleaning the surface of an electrostatic chuck of a semiconductor apparatus.

### 2. BACKGROUND OF THE INVENTION

With the continuous progress of technology, electronics products become indispensable to our daily life. As the precision of electronic products grows higher, so does the competition. Every electronics company is doing their best to improve their manufacturing process so as to raise the yield and enhance of production efficiency.

In the process of physical vapor deposition (which is referred as PVD hereinafter), oxidative contaminant acuminated on the electrostatic chuck will possibly cause the wrong orientation of the wafer on the electrostatic chuck, moreover, will even cause the wafer to slide and then induce the backside pressure fault or splintering of the wafer. In the conventional methods, a clean procedure is being performed only when the accumulation of oxidative contaminant causes the yield of the manufacturing process to drop. Also, the conventional clean methods cannot remove the oxidative contaminants completely such that the oxidative contaminants are soon acuminated in the manufacturing process causing the probability of splintering to increase and the yield of the process to decrease.

To sum up the above description, the conventional methods for cleaning the surface of an electrostatic chuck include at least the following disadvantages:
a. Oxidative contaminants acuminated on the electrostatic chuck cannot be removed completely and thus causes the wafer to splinter or to slide inducing backside pressure fault.
b. The oxidative contaminants cannot be cleaned in advance, but a clean procedure is being performed only when the accumulation of oxidative contaminant causes the yield of the manufacturing process to drop.
c. The poor yield of the manufacturing process causes the probability of splintering to increase that results in higher production cost and lower market competitiveness.
d. The parameters of the cleaning procedure cannot be quantified for operators performing the procedure to follow such that the quality of the clean procedure can not be assured.

### SUMMARY OF THE INVENTION

As is apparent from the above-noted problem, it is therefore an object of this present invention to provide a method for cleaning the surface of an electrostatic chuck of a semiconductor apparatus by which oxidative contaminants can be removed completely to avoid backside pressure fault caused by wafer slipping or wafer splintering.

Another object of this invention is to provide a method for cleaning the surface of an electrostatic chuck of a semiconductor apparatus by which the acuminated oxidative contaminants can be reduced effectively to improve the yield of the manufacturing process and extend the intermission between cleaning procedures required to remove oxidative contaminants for lower the maintenance cost of the semiconductor apparatus.

To achieve the above-noted objects, this invention provides a method for cleaning the surface of an electrostatic chuck of a semiconductor apparatus. The semiconductor apparatus includes a sputtering chamber having an electrostatic chuck inside for electrostatically clamps onto a wafer. The cleaning method of the present invention includes the steps of: adjusting the semiconductor apparatus to a cleaning state; generating a type of plasma at the cleaning state for removing the oxidative contaminants accumulated on the electrostatic chuck; and adjusting the semiconductor apparatus to a discharging state to stop the plasma from generating.

The adjustment of the semiconductor apparatus to the cleaning state includes at least three steps: inserting a protective gas; adjusting the RF power to an appropriate range; and maintaining the RF power in the appropriate range for a period of time. The adjustment of the semiconductor apparatus to the discharging state includes at least two steps: resetting the radio frequency power of the electrostatic chuck to zero; and discharging the protective gas from the sputtering chamber.

The method for cleaning the surface of an electrostatic chuck of a semiconductor apparatus according to the present invention can improve the yield of the manufacturing process, reduce the probability of splintering, lower the production cost and modularize the cleaning setting of the electrostatic chuck for the operators to follow and assure the cleaning quality.

### BRIEF DESCRIPTION OF THE DRAWINGS

FIG. 1 is a schematic view showing an electrostatic chuck of a semiconductor apparatus according to a preferred embodiment of the present invention.

FIG. 2 is a diagram illustrating the method for cleaning the surface of an electrostatic chuck of a semiconductor apparatus according to a preferred embodiment of the present invention.

### DESCRIPTION OF THE PREFERRED EMBODIMENT

The above and other objects and the nature and feature of the present inventions will be more apparent from the detailed description of preferred embodiments, taken in conjunction with the drawings.

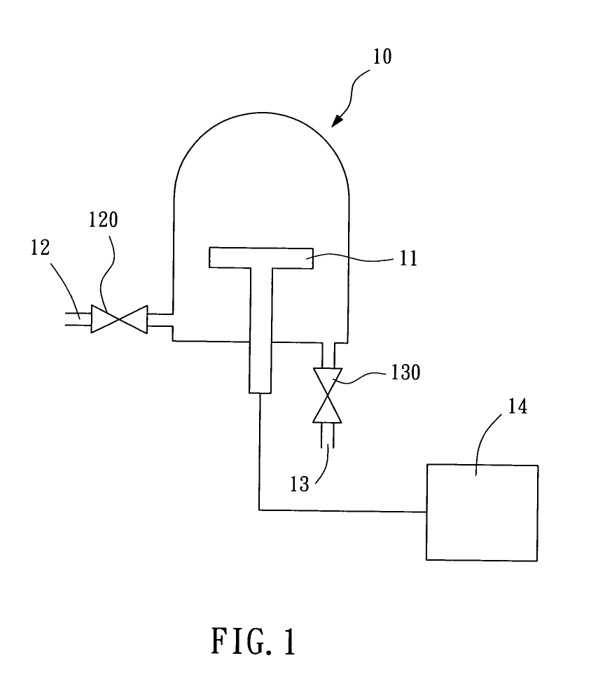

Referring to FIG. 1, which is a schematic view showing an electrostatic chuck of a semiconductor apparatus according to a preferred embodiment of the present invention. The semiconductor apparatus includes a sputtering chamber 10 having an electrostatic chunk 11 (which is referred as E-chunk hereinafter). An air inlet 12 and an air outlet 13 connecting to the sputtering chamber 10 are coupled to an inlet airflow controlling valve 120 and an outlet airflow controlling valve 130 respectively. The E-chunk 11 is coupled to a radio frequency producer 14 (hereafter RF producer 14). In the process of PVD, the E-chunk 11 is configured for holding a wafer for follow-up processes. However, since oxidative contaminants are likely to acuminate on the backside of wafer, the surface of the E-chunk 11 generally will have oxidative contaminants resided thereon. In this case, the wafer can not be oriented precisely on the surface of the E-chunk; which will probably slide and cause backside pressure fault or splintering. The air inlet 12, as implied in the name, is usually used for inletting protective gas and the inlet airflow is controlled by the inlet airflow controlling valve 120; for the same reason, the air outlet 13, as implied in the name, is usually used for outletting gas and the outlet airflow is controlled by the outlet airflow controlling valve 130. The RF producer 14 can provide the necessary RF power for E-chunk.

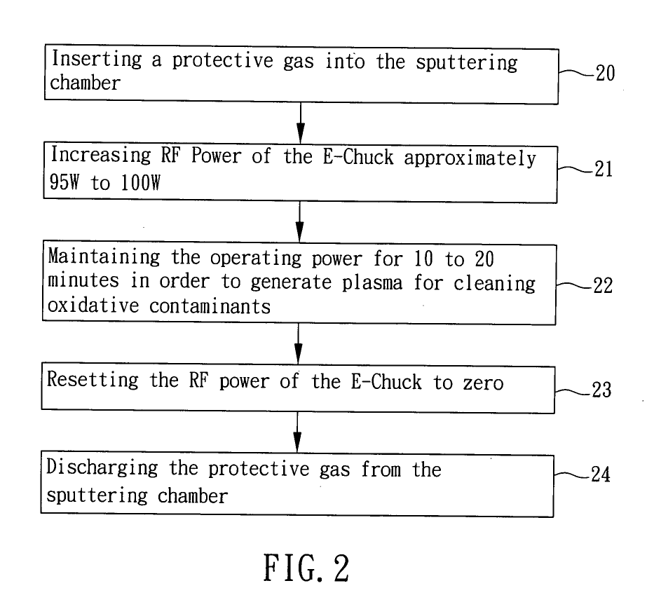

Referring to FIG. 2, a schematic view of the preferred embodiment of the method for cleaning the surface of an electrostatic chuck of semiconductor apparatus of the present invention in use is shown. This method includes the steps of:

Step 20: A protective gas is inserted into the sputtering chamber and Argon is the preferred gas of the present invention. The airflow of Argon is controlled approximately in the ranged of 5 sccm to 28 sccm. Argon functions as the necessary impacting gas particles for generating plasma.

Step 21: The RF Power of the E-chunk is increased to approximately 95W to 100W and the Argon particles are excited to impact by an external electrical field to ionize into plasma for using in the following cleaning procedure. The external electric field required for generating plasma is usually referred as the operating power. In the preferred embodiment of the present invention, 100W operating power is the most appropriate.

Step 22: The operating power is maintained for 10 to 20 minutes in order to generate plasma for cleaning oxidative contaminants. In this embodiment, RF power of the E-chunk is lasted over at least 95W and ten minutes, preferably 20 minutes, such that the internal electric field will accelerate the charged particles to impact the Argon molecules, and thus, the Argon molecules is ionized into plasma that can decompose the oxidative contaminants on the E-chunk.

In addition, it is noted that the above-mentioned parameters can be modularized as following: the RF power is set for approximately 95W to 100 W; the airflow is set for 5 sccm to 28 sccm; and the period of maintaining the operating power is set for 10 to 20 minutes. Thus, the operator of the semiconductor apparatus can perform the cleaning procedure simply by selecting a clean state after without manual adjustment so that the manufacturing process can be standardized and the production efficiency can be improved.

Step 23: The RF power of the E-chunk is reset to zero after the cleaning procedure, and the same time that the plasma of the semiconductor apparatus is stopped.

Step 24: The protective gas, i.e. Argon, in the sputtering chamber is discharged and the semiconductor apparatus is conditioned back to an usual state to finish the cleaning procedure.

Also, The processes for resetting the RF power of the E-chunk to zero and discharging the protective gas are modularized and defined as a discharging state that can stop the plasma from generating and condition the semiconductor apparatus back to the original state.

To sum up, the invention provides a method for cleaning the surface of an electrostatic chuck of a semiconductor apparatus. The method can remove the oxidative contaminants completely to avoid backside pressure fault caused by splintering or sliding of the wafer so as to improve the yield of process. Moreover, the method of the present invention can modularize the parameters of the cleaning procedure of the E-chunk to benefit operators for working. It is therefore understood that although the present invention has been specifically disclosed with the preferred embodiment and examples that cannot limit the scope of this invention. Modifications to the design concerning methods, such as different protective gas, different RF power of E-chunk and different lasting period for maintaining the RF power, will be apparent to those skilled in the art and such modifications and variations are considered to be equivalent to and within the scope of the disclosed invention and the appended claims.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments which do not depart from the spirit and scope of the invention.

1. A method for cleaning the surface of an electrostatic chuck of a semiconductor apparatus, said semiconductor apparatus comprising a sputtering chamber having an electrostatic chuck, said method comprising:
inserting a protective gas into said sputtering chamber;
adjusting a RF power of said electrostatic chuck to an operating power; and
maintaining said RF power at said operating power for a period of at least ten minutes.

2. The method of claim 1, wherein after maintaining said RF power at said operating power for at least ten minutes, said method further comprises:
resetting the RF power of said electrostatic chuck to zero; and
discharging said protective gas.

3. The method of claim 1, wherein said protective gas is Argon.

4. The method of claim 3, wherein the airflow of Argon is ranged between 5 sccm and 28 sccm.

5. The method of claim 1, wherein said operating power is ranged between 95W to 100W.

6. The method of claim 5, wherein said operating power is 100W.

7. The method of claim 1, wherein said period of maintaining said RF power at said operating power is twenty minutes.

8. A method for cleaning the surface of an electrostatic chuck of a semiconductor apparatus, said semiconductor apparatus comprising a sputtering chamber having an electrostatic chuck, said method comprising:
adjusting the semiconductor apparatus to a cleaning state, wherein said cleaning comprises generating plasma for removing oxidative contaminants accumulated on the electrostatic chuck; and
adjusting the semiconductor apparatus to a discharging state to stop the plasma.

9. The method of claim 8, wherein said cleaning state comprises:
inserting a protective gas into said sputtering chamber;
adjusting a RF power of said electrostatic chuck to within an appropriate range; and
maintaining said RF power within said appropriate range for lasting a period of time.

10. The method of claim 9, wherein said protective gas is Argon.

11. The method of claim 10, wherein the airflow of Argon is ranged between 5 sccm and 28 sccm.

12. The method of claim 9, wherein said operating power is ranged between 95W to 100W.

13. The method of claim 9, wherein said period of time for maintaining said RF power within said appropriate range is ranged between ten to twenty minutes.

14. The method of claim 8, wherein said discharging state comprises:
resetting the RF power of said electrostatic chuck to zero; and
discharging said protective gas.
